(19) United States
(12) Patent Application Publication
(10) Pub. No.: US 2008/0253165 A1
(43) Pub. Date: Oct. 16, 2008

(54) Method of Manufacturing a Memory Device, Memory Device, Cell, Integrated Circuit, Memory Module, and Computing System

(76) Inventor: Philippe Blanchard, Moigny sur Ecole (FR)

Correspondence Address: SLATER & MATSIL, L.L.P., 17950 PRESTON ROAD, SUITE 1000, DALLAS, TX, 75252, US

(21) Appl. No.: 11/733,696

(22) Filed: Apr. 10, 2007

(51) Int. Cl. G11C 11/00; H01R 43/00

(52) U.S. Cl. 365/148; 29/885

(57) ABSTRACT

In one embodiment of the present invention, a method of fabricating a memory device includes: providing a composite structure including a resistivity changing layer and a first conductive layer disposed on or above the resistivity changing layer, forming a second conductive layer on or above the first conductive layer, and patterning the second conductive layer such that at least a part of the patterned second conductive layer is usable as a via for contacting the first conductive layer.

### BRIEF DESCRIPTION OF THE DRAWINGS

For a more complete understanding of exemplary embodiments of the present invention and the advantage thereof, reference is now made to the following description taken in conjunction with the accompanying drawings, in which:

FIG. 1A shows a schematic cross-sectional view of a solid electrolyte memory cell set to a first memory state;

FIG. 1B shows a schematic cross-sectional view of a solid electrolyte memory cell set to a second memory state;

FIG. 2A shows a fabricating stage of a method of fabricating a solid electrolyte memory device according to one embodiment of the present invention;

FIG. 2B shows a fabricating stage of a method of fabricating a solid electrolyte memory device according to one embodiment of the present invention;

FIG. 2C shows a fabricating stage of a method of fabricating a solid electrolyte memory device according to one embodiment of the present invention;

FIG. 3A shows a fabricating stage of a method of fabricating a solid electrolyte memory device according to one embodiment of the present invention;

FIG. 3B shows a fabricating stage of a method of fabricating a solid electrolyte memory device according to one embodiment of the present invention;

FIG. 3C shows a fabricating stage of a method of fabricating a solid electrolyte memory device according to one embodiment of the present invention;

FIG. 3D shows a fabricating stage of a method of fabricating a solid electrolyte memory device according to one embodiment of the present invention;

FIG. 3E shows a fabricating stage of a method of fabricating a solid electrolyte memory device according to one embodiment of the present invention;

FIG. 4 shows a flow chart of a method of fabricating a solid electrolyte memory device according to one embodiment of the present invention;

FIG. 5 shows a flow chart of a method of fabricating a solid electrolyte memory device according to one embodiment of the present invention;

FIG. 6 shows a schematic cross-sectional view of a part of a solid electrolyte memory device according to one embodiment of the present invention;

FIG. 7 shows a schematic drawing of a computing system according to one embodiment of the present invention;

FIG. 8A shows a perspective view of a memory module according to one embodiment of the present invention;

FIG. 8B shows a perspective view of a memory module according to one embodiment of the present invention;

FIG. 9 shows a cross-sectional view of a phase changing memory cell;

FIG. 10 shows a schematic drawing of a memory device including resistivity changing memory cells;

FIG. 11A shows a cross-sectional view of a carbon memory cell set to a first switching state;

FIG. 11B shows a cross-sectional view of a carbon memory cell set to a second switching state;

FIG. 12A shows a schematic drawing of a resistivity changing memory cell; and

FIG. 12B shows a schematic drawing of a resistivity changing memory cell.

### DETAILED DESCRIPTION OF ILLUSTRATIVE EMBODIMENTS

For sake of simplicity, it is assumed in the following description that the resistivity changing memory device is a solid electrolyte memory device, and that the resistivity changing layer is a solid electrolyte layer. However, the present invention is also applicable to other types of resistivity changing memory devices and resistivity changing layers.

According to one embodiment of the present invention, a method of fabricating a solid electrolyte memory device is provided, the method includes: providing a composite structure including a solid electrolyte layer and a first conductive layer disposed on or above the solid electrolyte layer; forming a second conductive layer on or above the first conductive layer; and patterning the second conductive layer such that at least a part of the patterned second conductive layer is usable as a via for contacting the first conductive layer.

According to one embodiment of the present invention, a method of fabricating an integrated circuit including a solid electrolyte memory device is provided, the method includes: providing a composite structure including a solid electrolyte layer and a first conductive layer disposed on or above the solid electrolyte layer; forming a second conductive layer on or above the first conductive layer; and patterning the second conductive layer such that at least a part of the patterned second conductive layer is usable as a via for contacting the first conductive layer.

According to this embodiment, vias for contacting the first conductive layer are formed by structuring the second conductive layer which has been deposited on the first conductive layer. Then, the areas between the remaining parts of the second conductive layers may be filled with insulating material. Compared to standard methods of generating vias (according to standard methods, an isolation layer is deposited on the first conductive layer; then, trenches are generated within the isolation layer; tast, the trenches are filled with conductive material, wherein the filled trenches represent the vias), the method of generating vias according to this embodiment has the effect that a delamination of the solid electrolyte layer due to the generation of the vias is less likely to occur. Therefore, the quality and reproducibility of solid electrolyte memory devices fabricated in accordance with the method according to this embodiment can be improved.

According to one embodiment of the present invention, an isolation layer is provided on the patterned second conductive layer. The thickness of the isolation layer is reduced until the vertical level of the top surface of the second isolation layer equals or falls below the vertical level of the top surface of the structured second conductive layer.

According to one embodiment of the present invention, the composite structure is patterned after having patterned the second conductive layer and before providing the second conductive layer. In this way, the danger of delamination of the solid electrolyte layer can be further reduced.

According to one embodiment of the present invention, the second conductive layer includes or consists of tungsten (W).

According to one embodiment of the present invention, the second conductive layer is deposited using a PVD (physical vapour deposition) process. However, also other deposition methods like CVD (chemical vapour deposition) may be used.

According to one embodiment of the present invention, the PVD process is carried out at temperatures below 300° C.

According to one embodiment of the present invention, the solid electrolyte layer includes or consists of chalcogenide.

According to one embodiment of the present invention, the thickness of the isolation layer is reduced using a chemical mechanical polishing process (CMP).

According to one embodiment of the present invention, the material of the second masking layer includes or consists of insulating material, for example oxide.

According to one embodiment of the present invention, the material of the second masking layer includes or consists of the same material as that of the isolation layer.

According to one embodiment of the present invention, the isolation layer is provided on the patterned second masking layer.

According to one embodiment of the present invention, the patterning of the second conductive layer is carried out by depositing a first masking layer on the second conductive layer, patterning the first masking layer using a lithography process, and patterning the second conductive layer, wherein the patterned first masking layer serves as a mask for patterning the second conductive layer.

According to one embodiment of the present invention, the patterning of the composite structure is carried out by depositing a second masking layer on the composite structure, patterning the second masking layer using a lithography process, and patterning the composite structure, wherein the patterned second masking layer serves as a mask for patterning the composite structure.

According to one embodiment of the present invention, a method of manufacturing a solid electrolyte memory cell is provided, and includes: providing a composite structure including a solid electrolyte layer and a first conductive layer arranged on or above the solid electrolyte layer; forming a second conductive layer on or above the first conductive layer; depositing a first masking layer on or above the second conductive layer; patterning the first masking layer (using, e.g., a lithography process); patterning the second conductive layer such that at least a part of the patterned second conductive layer is usable as a via for contacting the first conductive layer, wherein the patterned first masking layer serves as a mask for patterning the second conductive layer; removing the patterned first masking layer, depositing a second masking layer on or above the composite structure, patterning the second masking layer (using, e.g., a lithography process); patterning the composite structure, wherein the patterned second masking layer serves as a mask for patterning the composite structure; depositing an isolation layer on or above the patterned composite structure; and reducing the thickness of the isolation layer until the vertical level of the top surface of the second isolation layer equals or is lower than the vertical level of the top surface of the structured second conductive layer.

According to one embodiment of the present invention, a method of manufacturing an integrated circuit including a solid electrolyte memory cell is provided, and includes: providing a composite structure including a solid electrolyte layer and a first conductive layer arranged on or above the solid electrolyte layer; forming a second conductive layer on or above the first conductive layer; depositing a first masking layer on or above the second conductive layer; patterning the first masking layer (using, e.g., a lithography process); patterning the second conductive layer such that at least a part of the patterned second conductive layer is usable as a via for contacting the first conductive layer, wherein the patterned first masking layer serves as a mask for patterning the second conductive layer; removing the patterned first masking layer, depositing a second masking layer on or above the composite structure, patterning the second masking layer (using, e.g., a lithography process); patterning the composite structure, wherein the patterned second masking layer serves as a mask for patterning the composite structure; depositing an isolation layer on or above the patterned composite structure; and reducing the thickness of the isolation layer until the vertical level of the top surface of the second isolation layer equals or is lower than the vertical level of the top surface of the structured second conductive layer.

According to one embodiment of the present invention, the thickness reduction is carried out using a chemical mechanical polishing process (CMP).

According to one embodiment of the present invention, the second conductive layer comprises or consists of tungsten.

According to one embodiment of the present invention, the second conductive layer is deposited using a PVD process.

According to one embodiment of the present invention, the PVD process is carried out at temperatures below 300° C.

According to one embodiment of the present invention, a solid electrolyte memory device is provided, and includes: a composite structure including a solid electrolyte layer and an electrode layer disposed on or above the solid electrolyte layer; and at least one conductive via arranged above the electrode layer, wherein the at least one conductive via directly contacts the electrode layer.

The term “directly” means that no intermediate layer of conductive material is provided between the at least one via and the electrode layer and/or between the at least one via and isolation material surrounding the at least one via. For example, according to one embodiment of the present invention, no adhesive layer is provided between the at least one via and the electrode layer. Normally, as already indicated before, an isolation layer is provided on the electrode layer. Then, the isolation layer is patterned in order to generate a trench structure within the isolation layer. The trench structure is filled with conductive material, thereby forming the vias. In order to insure a sufficient adhesive force between the vias and the electrode layer and/or the isolation material surrounding the vias, an adhesive layer is deposited on the isolation layer after having formed the trench structure, thereby covering the whole or at least a part of the surface of the trench structure. According to this embodiment, such an adhesive layer can be omitted. As a consequence, the fabrication process of solid electrolyte memory devices is facilitated. An intermediate layer can be omitted since an intermediate layer like an adhesive layer or seed layer is not needed by the methods of generating vias according to embodiments of the present invention.

According to one embodiment of the present invention, the at least one via includes or consists of tungsten.

According to one embodiment of the present invention, the at least one via is embedded into a layer of insulating material, wherein the vertical level of the top surface of the layer of insulating material equals or is lower than the vertical level of the top surface of the at least one via.

According to one embodiment of the present invention, the electrode layer includes a lower part and an upper part consisting of different materials, respectively.

According to one embodiment of the present invention, the lower part comprises or consists of silver, and the upper part comprises or consists of tantalum nitride or copper.

According to one embodiment of the present invention, the thickness of the upper part lies between 50 nm to 150 nm.

According to one embodiment of the present invention, the thickness of the at least one via lies between 250 nm and 400 nm.

According to one embodiment of the present invention, a solid electrolyte memory device is provided, including: a composite structure means including a solid electrolyte means and an electrode means arranged on or above the solid electrolyte means; and at least one conductive via means arranged on or above the electrode means, wherein the at least one conductive via means directly contacts the electrode means.

According to one embodiment of the present invention, the solid electrolyte memory means may be a solid electrolyte memory device using computing devices, the composite structure means may be a stack of several layers, the solid electrolyte means may be a solid electrolyte layer, the electrode means may be an electrode layer, and the conductive via means may be conductive vias.

According to one embodiment of the present invention, a cell is provided, and includes: a composite structure including a solid electrolyte layer and an electrode layer disposed on or above the solid electrolyte layer; and at least one conductive via arranged above the electrode layer, wherein the at least one conductive via directly contacts the electrode layer. The cell may for example be a memory cell. However, the present invention is not restricted thereto. The cell may for example also be used as tunable resistance unit in a tunable resistor.

According to one embodiment of the present invention, a memory module comprising at least one memory device, memory cell or integrated circuit according to the present invention is provided. According to one embodiment of the present invention, the memory module is stackable.

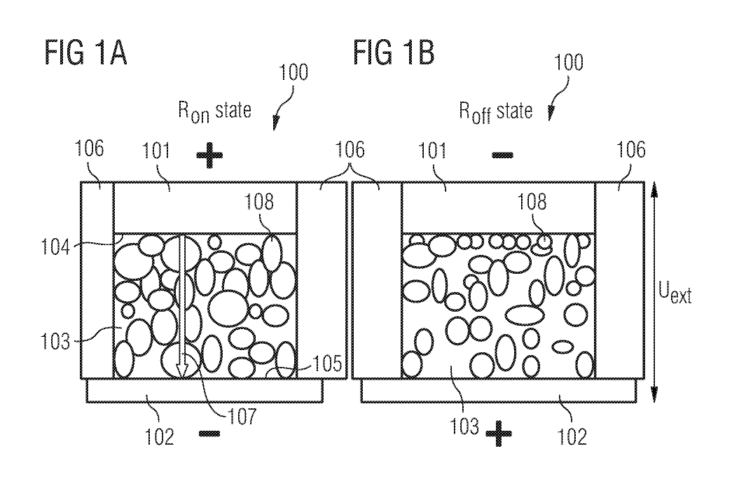

Since the embodiments of the present invention can be applied to solid electrolyte devices like CBRAM (conductive bridging random access memory) devices, in the following description, making reference to FIGS. 1A and 1B, a basic principle underlying CBRAM devices will be explained.

As shown in FIG. 1A, a CBRAM cell 100 includes a first electrode 101 a second electrode 102, and a solid electrolyte block (in the following also referred to as ion conductor block) 103 that includes the active material and that is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, and the second surface 105 is the bottom surface of the ion conductor 103. In the same way, the first electrode 101 generally is the top electrode, and the second electrode 102 is the bottom electrode of the CBRAM cell 100. One of the first electrode 101 and the second electrode 102 is a reactive electrode, the other one is an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention, however, is not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may, for example, range between 5 nm and 500 nm. The thickness of the first electrode 101 may, for example, range between 10 nm and 100 nm. The thickness of the second electrode 102 may, for example, range between 5 nm and 500 nm, between 15 nm to 150 nm, or between 25 nm and 100 nm. It is to be understood that the present invention is not restricted to the above-mentioned materials and thicknesses.

In the context of this description, chalcogenide material (ion conductor) is to be understood for example as any compound containing oxygen, sulphur, selenium, germanium and/or tellurium. In accordance with one embodiment of the invention, the ion conducting material is for example a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage, as indicated in FIG. 1A, is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In the case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107.

In order to determine the current memory status of a CBRAM cell 100, for example a sensing current is routed through the CBRAM cell 100. The sensing current experiences a high resistance in case no conductive bridge 107 exists within the CBRAM cell, and experiences a low resistance in case a conductive bridge 107 exists within the CBRAM cell. A high resistance may for example represent “0”, whereas a low resistance represents “1”, or vice versa. The memory status detection may also be carried out using sensing voltages.

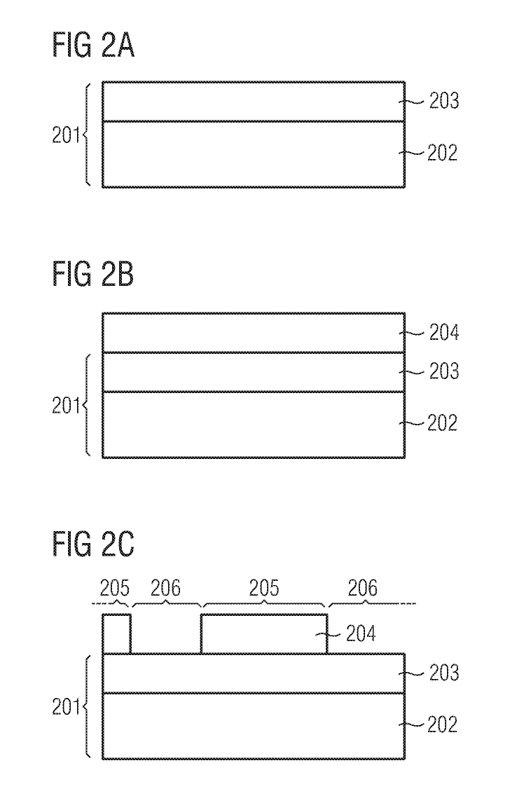

In the following description, making reference to FIGS. 2A to 2C, a method 200 of fabricating a solid electrolyte memory device according to one embodiment of the present invention will be explained.

In a first fabricating stage (FIG. 2A), a composite structure 201 including a solid electrolyte layer 202 and a first conductive layer 203 is provided. The solid electrolyte layer 202 may for example include or consist of chalcogenide material, the first conductive layer 203 may for example include or consist of silver (Ag) or copper (Cu). In a second fabricating stage (FIG. 2B), a second conductive layer 204 is provided on the first conductive layer 203. The second conductive layer 204 may, for example, include or consist of tungsten (W). In a third fabricating stage (FIG. 2C), the second conductive layer 204 is patterned. At least one part 205 of the second conductive layer 204, which is not removed by the patterning process, may be used as a via for contacting the first conductive layer 203. In order to use the parts 205 as vias, insulating material may be filled into the trenches/gaps/areas 206 between the parts 205 of the second conductive layer 204 which are generated by the patterning process.

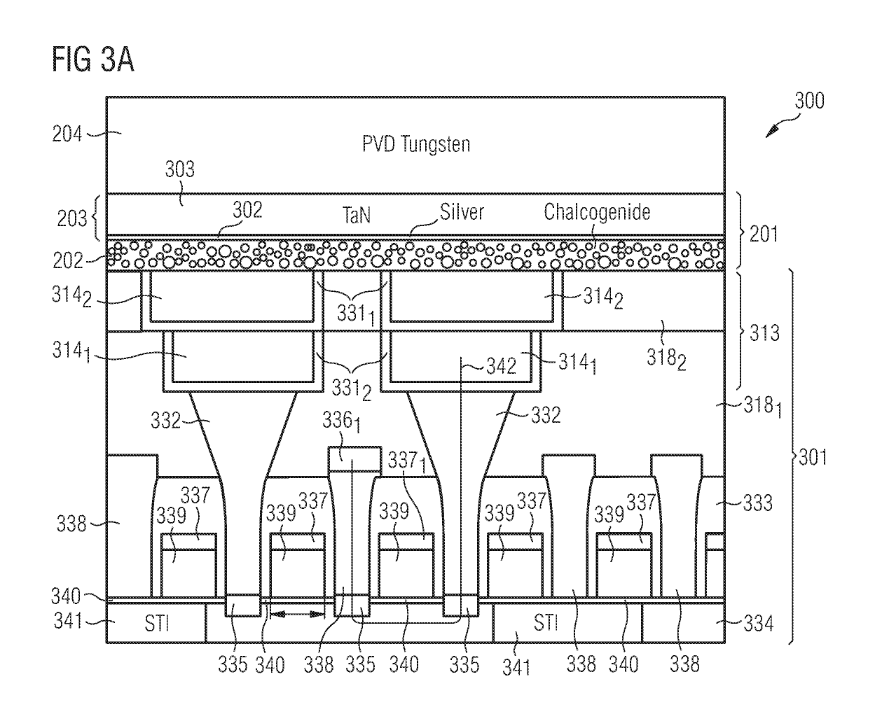

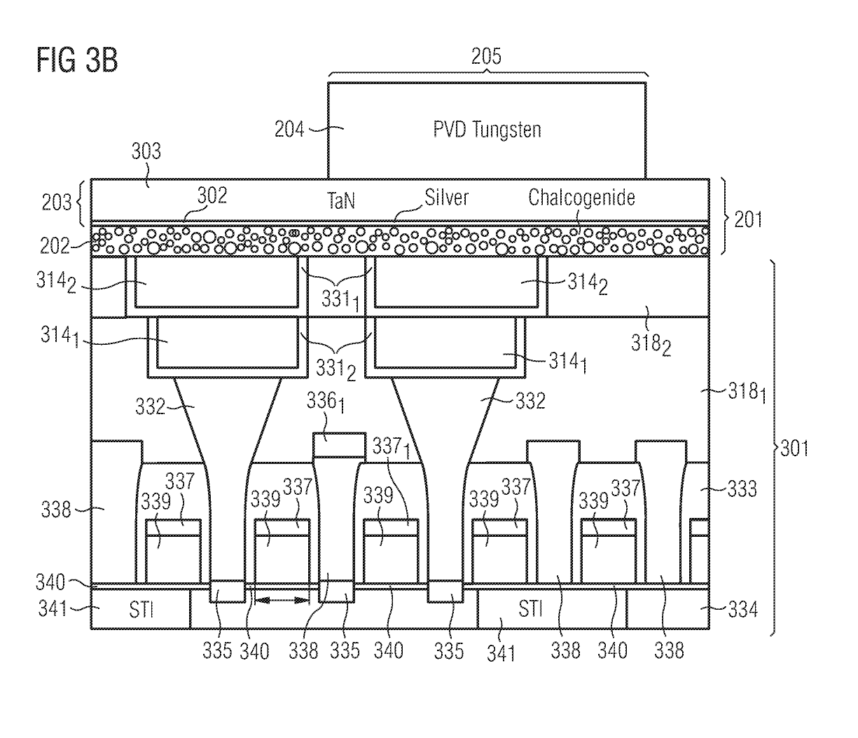

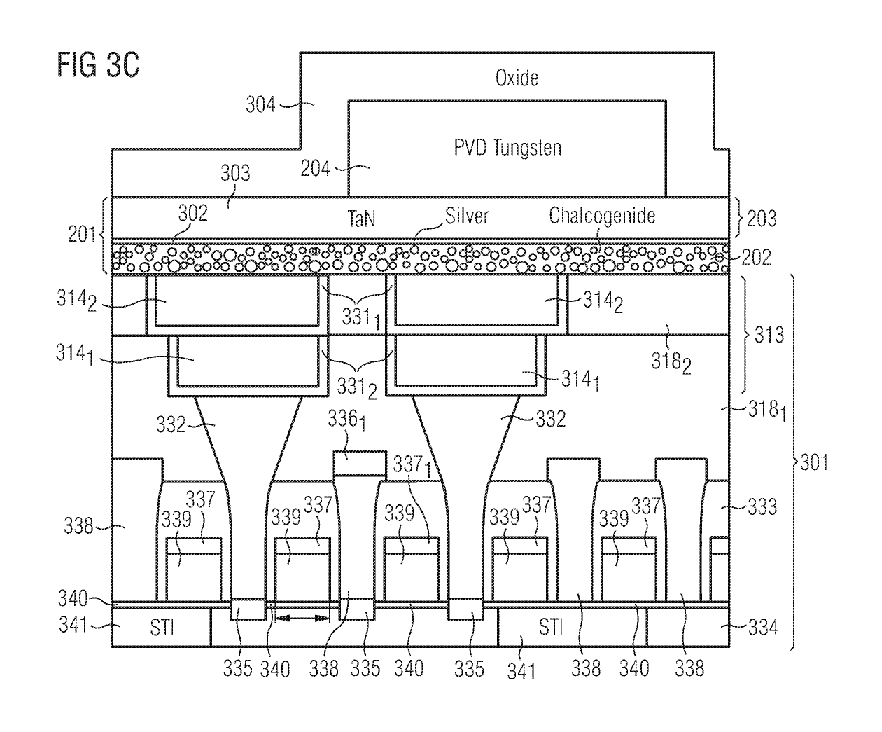

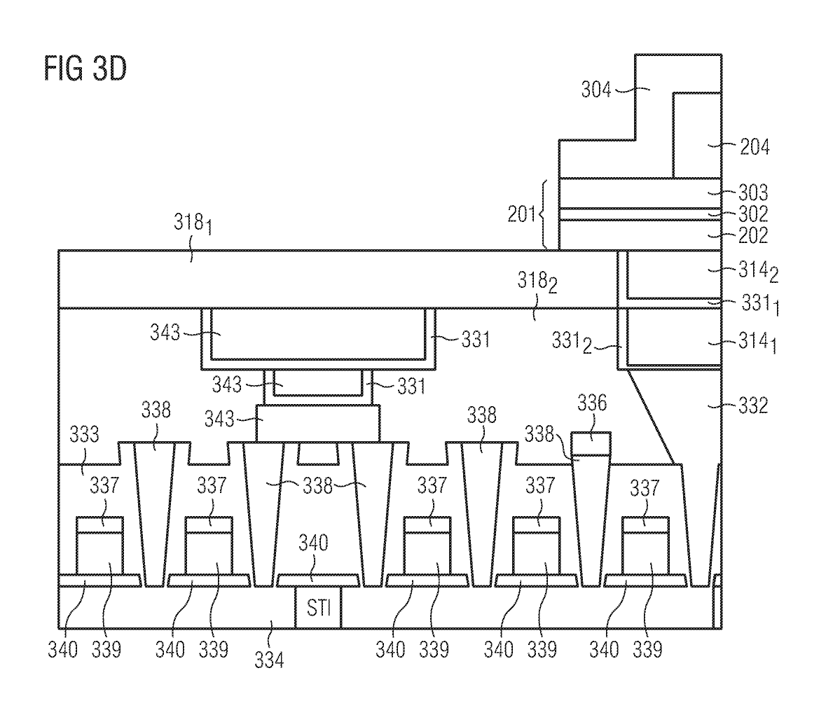

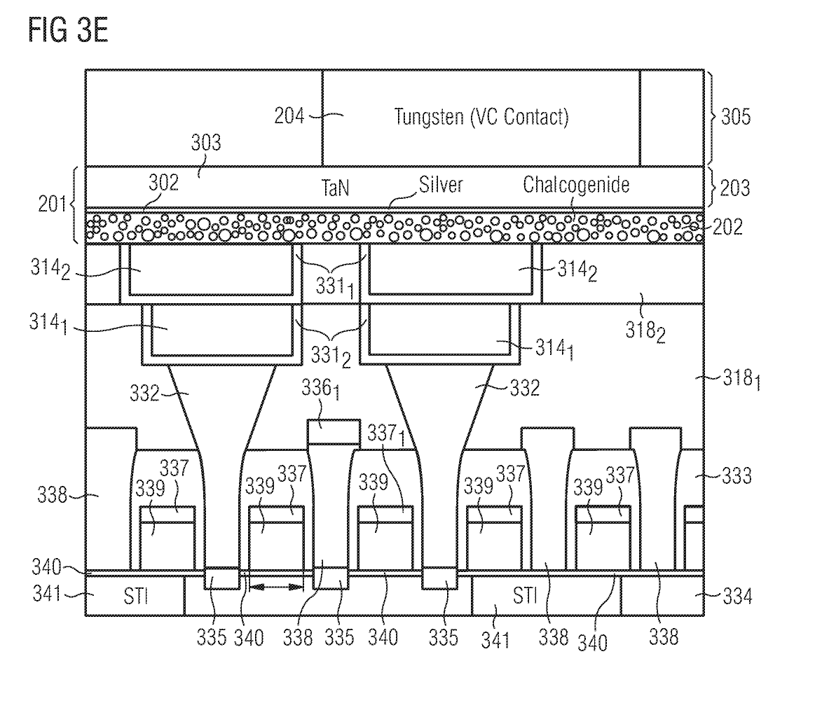

In the following description, making reference to FIGS. 3A to 3E, a method 300 of fabricating a solid electrolyte memory device according to one embodiment of the present invention will be explained.

FIG. 3A shows a fabricating stage in which a composite structure 201 includes a solid electrolyte layer 202 and a first conductive layer 203 has been provided on a structure 301 including several electrodes, conductive lines, select devices, etc. In detail:

FIG. 3A shows a structure 301 having a bottom electrode layer 313 includes several bottom electrodes 314. Each bottom electrode 314 includes a first plug 314₁ and a second plug 314₂ stacked above each other in this order. The second plugs 314₂ directly contact the solid electrolyte layer 202. The bottom electrodes 314 are isolated against each other by a first isolating layer 318₁ and a second isolating layer 318₂ stacked above each other in this order. The first plugs 314₁ are covered by first adhesive layers 331₁ except of their upper surfaces which directly contact the solid electrolyte layer 202. The lower surfaces of the first plugs 314₁ are electrically connected to the second plugs 314₂ arranged below the first plugs 314₁, the second plugs 314₂ being covered by second adhesive layers 331₂. The lower surfaces of the second plugs 314₂ are electrically connected (indirectly via the second adhesive layers 331₂) to first conductive contacts 332 (for example poly silicon contacts) extending through an isolation layer 333 arranged below the first isolating layer 318₁ into a substrate 334. At the junctions between the conductive contacts 332 and the substrate 334, regions 335 of the opposite conductive type as that of the substrate 334 are arranged within the substrate 334. Bit lines 336 are formed within the first isolating layer 318₁. Further, word lines 337 are arranged within the isolation layer 333. The bit lines 336 are electrically connected to the regions 335 via second conductive contacts 338 (for example poly silicon contacts). The word lines 337 are electrically connected to conductive elements 339 (for example poly silicon contacts), which extend to the top surface of the substrate 334, however are isolated against the substrate 334 by isolation layers 340 (gate isolation layers). Further, isolation areas 341, which comprise isolation material, are provided within the substrate 334, the isolation areas 341 deactivating corresponding conductive contacts 338 and conductive elements 339 arranged above the isolation areas 341.

The conductive elements 339 function as gates, the regions 335 as source regions and drain regions. Each bottom electrode 314 can be selected by selecting one word line 337 and one bit line 336. In this case, a current flows through the selected bottom electrode 314, the corresponding first conductive contact 332, the region of the substrate 334 lying below the selected word line 337, and the corresponding second conductive contact 332 to the selected bit line 336. For example, a current path 342 will be formed assuming that the word line 337₁ and the bit line 336₁ are selected. Each structure comprising a first conductive contact 332, a region of the substrate 334 lying below the selected word line 337, a second conductive contact 332, and a bit line 336 can be interpreted as a selection device.

The first conductive layer 203 includes a top electrode layer 302, which may, for example, include or consist of silver, and a conductive layer 303 arranged above the top electrode layer 302 which may, for example, include or consist of tantalum nitride (TaN). A second conductive layer 204 is provided on the top surface of the conductive layer 303, i.e., on the top surface of the composite structure 201. The thickness of the second conductive layer 204 may, for example, lie between 250 nm up to 400 nm, for example 300 nm. The second conductive layer 204 may, for example, include or consist of tungsten (W). The second conductive layer 204 may, for example, be deposited on the composite structure 201 using a PVD (physical vapour deposition) process. The PVD process may, for example, be carried out at temperatures lying below 300° C. An effect of using temperatures below 300° C. is that the danger of delamination of the solid electrolyte layer 202 (e.g., a chalcogenide layer) can be strongly reduced. The thickness of the conductive layer 303 may, for example, be 50 nm up to 150 nm, for example, 100 nm.

FIG. 3B shows a fabricating stage obtained after having patterned the second conductive layer 204 down to the vertical level of the top surface of the conductive layer 303. Here, the whole second conductive layer 204 has been removed by the patterning process except of a part 205 which will serve as a via. The invention is not restricted to the generation of one single part 205. Instead, the patterning process of the second conductive layer 204 may also be carried out such that the second conductive layer 204 will be patterned into several parts 205, thereby generating two or more conductive vias. The process of patterning the second conductive layer 204 may, for example, be carried out by depositing a first masking layer (not shown) on the second conductive layer 204, patterning the first masking layer using a lithography process, and patterning the second conductive layer 204 using the patterned first masking layer as a mask for patterning the second conductive layer 204.

FIG. 3C shows a fabricating processing stage in which an isolation layer 304 has been deposited on the top surface of the structure shown in FIG. 3B, i.e., on the top surface of the exposed conductive layer 303 and on the top surface and side surfaces of the parts 205 of the second conductive layer 204 which have remained after the patterning process of the second conductive layer 204. The isolation layer 304 may for example be an oxide layer.

FIG. 3D shows a fabricating stage in which the isolation layer 304 has been patterned (i.e., removed) within the peripheral area of the solid electrolyte memory device to be fabricated (in contrast to FIGS. 3A to 3C and 3E, FIG. 3D mainly shows a peripheral area of the memory device to be fabricated; only an ending section of the cell area (right part) of the memory device is shown. The patterning process of the isolation layer 304 may, for example, be carried out using a lithography process. Then, the composite structure 201 may be patterned (using, for example, an etching process) using the patterned isolation layer 304 as a mask (not shown). Within the peripheral area, several conductive elements 343 are provided.

FIG. 3E shows a fabricating stage in which, after having patterned the composite structure 201, a further isolation layer has been deposited on the structured isolation layer 304. Further, a composite structure 305 consisting of the isolation layer 304 and the further isolation layer has been reduced in its thickness, i.e., the thickness of the composite structure 305 is reduced until the vertical level of the top surface of the composite structure 305 is equal or lower than the vertical level of the top surface of the via (part 205 of the second conductive layer 204). In this way, the via is “opened”.

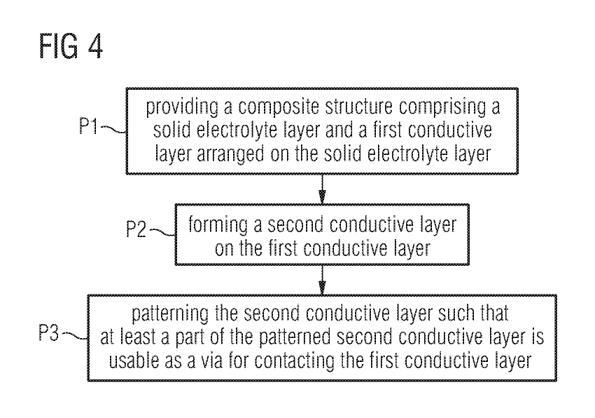

FIG. 4 shows a method of fabricating a solid electrolyte memory device according to one embodiment of the present invention.

In a first process P1, a composite structure comprised of a solid electrolyte layer and a first conductive layer arranged on the solid electrolyte layer is provided. In a second process P2, a second conductive layer is formed on the first conductive layer. In a third process P3, the second conductive layer is patterned such that at least a part of the patterned second conductive layer is usable as a via for contacting the first conductive layer.

FIG. 5 shows a further method of fabricating a solid electrolyte memory device according to one embodiment of the present invention. In a first process S1, a composite structure comprised of a solid electrolyte layer and a first conductive layer arranged on the solid electrolyte layer is provided. In a second process, a second conductive layer is deposited on the first conductive layer. In a third process S3, a first masking layer is deposited on the second conductive layer. In a fourth process S4, the first masking layer is patterned using a lithography process. In a fifth process S5, the second conductive layer is patterned such that at least a part of the patterned second conductive layer is usable as a via for contacting the first conductive layer, wherein the patterned first masking layer serves as a mask for patterning the second conductive layer. In a sixth process S6, the patterned first masking layer is removed. In a seventh process S7, the second masking layer is deposited on the composite structure. In an eighth process S8, the second masking layer is patterned using a lithography process. In a ninth process S9, the composite structure is patterned, wherein the patterned second masking layer serves as a mask for patterning the composite structure. In a tenth process S10, an isolation layer is deposited on the patterned composite structure. In an eleventh process S11, the thickness of the isolation layer is reduced until the vertical level of the top surface of the second isolation layer equals or is lower than the vertical level of the top surface of the structured second conductive layer.

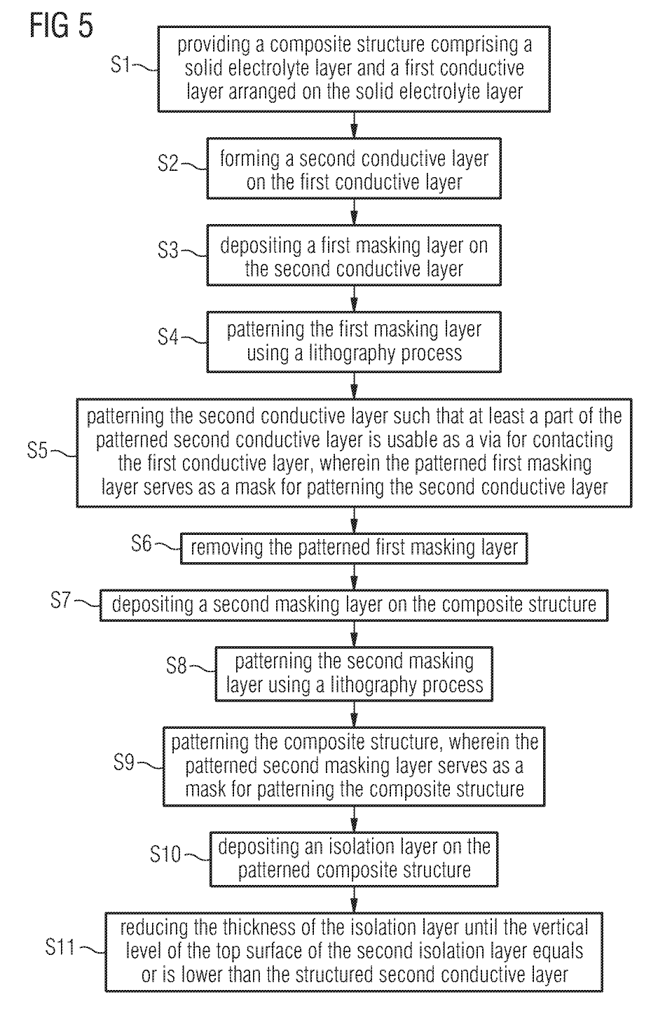

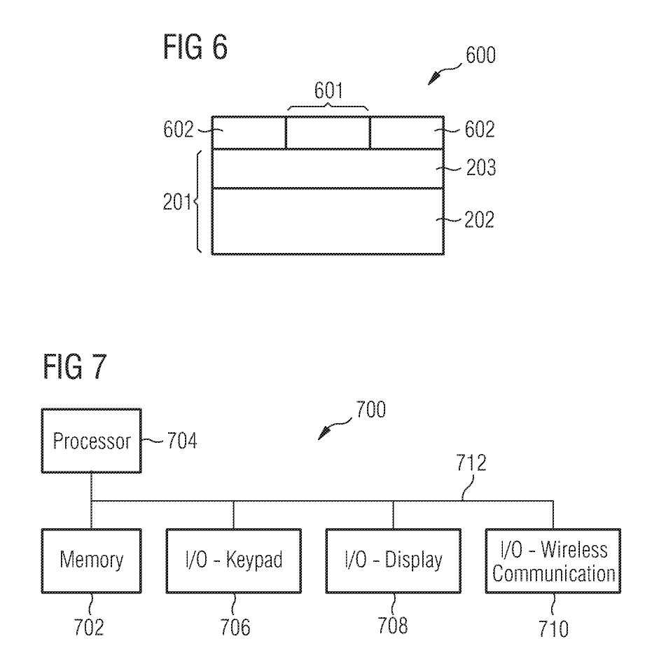

FIG. 6 shows a solid electrolyte memory device according to one embodiment of the present invention. The solid electrolyte memory device 600 includes a composite structure 201, which includes a solid electrolyte layer 202 and a first conductive layer 203 being arranged on the solid electrolyte layer 202. A conductive via 601 is arranged on the first conductive layer 203, the via 601 being surrounded by insulating material 602. The conductive via 601 directly contacts the first conductive layer 203, i.e., no adhesive layer or other intermediate layer like a seed layer is provided between the via 601 and the insulating material 602 and/or the top surface of the first conductive layer 203.

In accordance with some embodiments of the invention, resistivity changing memory devices that may include memory cells as described herein may be used in a variety of applications or systems, such as the illustrative computing system shown in FIG. 7. The computing system 700 includes a resistivity changing memory device 702. The system also includes a processing apparatus 704, such as a microprocessor or other processing device or controller, as well as input and output apparatus, such as a keypad 706, display 708, and/or wireless communication apparatus 710. The memory device 702, processing apparatus 704, keypad 706, display 708 and wireless communication apparatus 710 are interconnected by a bus 712.

The wireless communication apparatus 710 may have the ability to send and/or receive transmissions over a cellular telephone network, a WiFi wireless network, or other wireless communication network. It will be understood that the various input/output devices shown in FIG. 7 are merely examples. Memory devices including memory cells in accordance with embodiments of the invention may be used in a variety of systems. Alternative systems may include a variety input and output devices, multiple processors or processing apparatus, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied.

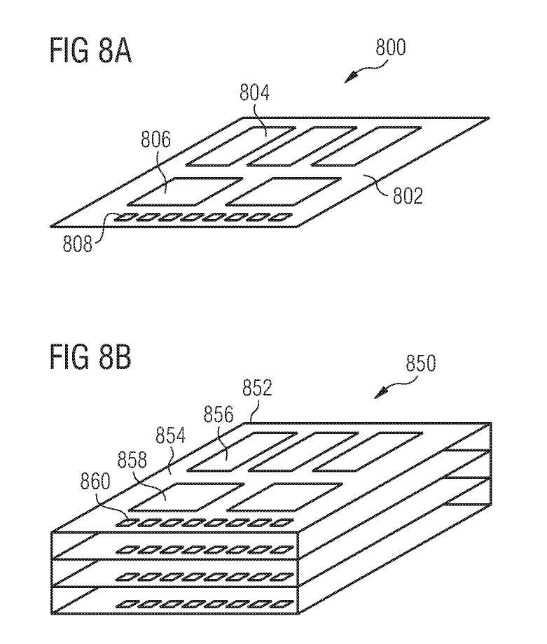

As shown in FIGS. 8A and 8B, in some embodiments, memory devices such as those described herein may be used in modules. In FIG. 8A, a memory module 800 is shown, on which one or more memory devices/memory cells/integrated circuits 804 are arranged on a substrate 802. The memory devices/memory cells/integrated circuits 804 may include numerous memory cells, each of which uses a memory element in accordance with an embodiment of the invention. The memory module 800 may also include one or more electronic devices 806, which may include memory, processing circuitry, control circuitry, addressing circuitry, bus interconnection circuitry, or other circuitry or electronic devices that may be combined on a module with a memory device, such as the memory devices/memory cells/integrated circuits 804. Additionally, the memory module 800 includes multiple electrical connections 808, which may be used to connect the memory module 800 to other electronic components, including other modules.

As shown in FIG. 8B, in some embodiments, these modules may be stackable, to form a stack 850. For example, a stackable memory module 852 may contain one or more memory devices 856, arranged on a stackable substrate 854. The memory device 856 contains memory cells that employ memory elements in accordance with an embodiment of the invention. The stackable memory module 852 may also include one or more electronic devices 858, which may include memory, processing circuitry, control circuitry, addressing circuitry, bus interconnection circuitry, or other circuitry or electronic devices that may be combined on a module with a memory device, such as the memory device 856. Electrical connections 860 are used to connect the stackable memory module 852 with other modules in the stack 850, or with other electronic devices. Other modules in the stack 850 may include additional stackable memory modules, similar to the stackable memory module 852 described above, or other types of stackable modules, such as stackable processing modules, control modules, communication modules, or other modules containing electronic components.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as “crystalline state”, whereas the crystallization state having a low degree of crystallization is also referred to as “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may routed through the phase changing material (or a sensing voltage may be applied across the phase changing material), thereby sensing the resistivity of the resistivity changing memory cell, which represents the memory state of the memory cell.

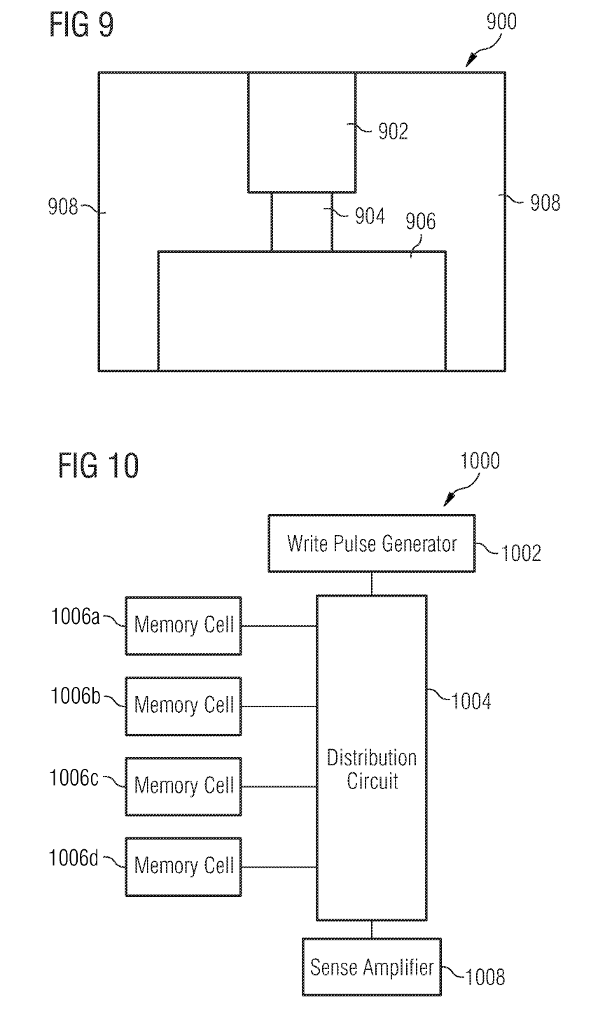

FIG. 9 illustrates a cross-sectional view of an exemplary phase changing memory cell 900 (active-in-via type). The phase changing memory cell 900 includes a first electrode 906, a phase changing material 904, a second electrode 902, and an insulating material 908. The phase changing material 904 is laterally enclosed by the insulating material 908. To use the phase changing memory cell in a memory cell, a selection device (not shown), such as a transistor, a diode, or another active device, may be coupled to the first electrode 906 or to the second electrode 902 to control the application of a current or a voltage to the phase changing material 904 via the first electrode 906 and/or the second electrode 902. To set the phase changing material 904 to the crystalline state, a current pulse and/or voltage pulse may be applied to the phase changing material 904, wherein the pulse parameters are chosen such that the phase changing material 904 is heated above its crystallization temperature, while keeping the temperature below the melting temperature of the phase changing material 904. To set the phase changing material 904 to the amorphous state, a current pulse and/or voltage pulse may be applied to the phase changing material 904, wherein the pulse parameters are chosen such that the phase changing material 904 is quickly heated above its melting temperature, and is quickly cooled.

The phase changing material 904 may include a variety of materials. According to one embodiment, the phase changing material 904 may include or consist of a chalcogenide alloy that includes one or more cells from group VI of the periodic table. According to another embodiment, the phase changing material 904 may include or consist of a chalcogenide compound material, such as GeSbTe, SbTe, GeTe or AgInSbTe. According to a further embodiment, the phase changing material 904 may include or consist of chalcogen free material, such as GeSb, GaSb, InSb, or GeGaInSb. According to still another embodiment, the phase changing material 904 may include or consist of any suitable material including one or more of the cells Ge, Sb, Te, Ga, Bi, Pb, Sn, Si, P, O, As, In, Se, and S.

According to one embodiment, at least one of the first electrode 906 and the second electrode 902 may include or consist of Ti, V, Cr, Zr, Nb, Mo, Hf, Ta, W, or mixtures or alloys thereof. According to another embodiment, at least one of the first electrode 906 and the second electrode 902 may include or consist of Ti, V, Cr, Zr, Nb, Mo, Hf, Ta, W and two or more cells selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 10 illustrates a block diagram of a memory device 1000 including a write pulse generator 1001, a distribution circuit 1004, phase changing memory cells 1006a, 1006b, 1006c, 1006d (for example phase changing memory cells 200 as shown in FIG. 2), and a sense amplifier 1008. According to one embodiment, a write pulse generator 1002 generates current pulses or voltage pulses that are supplied to the phase changing memory cells 1006a, 1006b, 1006c, 1006d via the distribution circuit 1004, thereby programming the memory states of the phase changing memory cells 1006a, 1006b, 1006c, 1006d. According to one embodiment, the distribution circuit 1004 includes a plurality of transistors that supply direct current pulses or direct voltage pulses to the phase changing memory cells 1006a, 1006b, 1006c, 1006d or to heaters being disposed adjacent to the phase changing memory cells 1006a, 1006b, 1006c, 1006d.

As already indicated, the phase changing material of the phase changing memory cells 1006a, 1006b, 1006c, 1006d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1008 is capable of determining the memory state of one of the phase changing memory cells 1006a, 1006b, 1006c, or 1006d in dependence on the resistance of the phase changing material.

To achieve high memory densities, the phase changing memory cells 1006a, 1006b, 1006c, 1006d may be capable of storing multiple bits of data, i.e., the phase changing material may be programmed to more than two resistance values. For example, if a phase changing memory cell 1006a, 1006b, 1006c, 1006d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 10 may also be applied in a similar manner to other types of resistivity changing memory cells like programmable metallization cells (PMCs), magento-resistive memory cells (e.g., MRAMs) or organic memory cells (e.g., ORAMs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 4A and 4B.

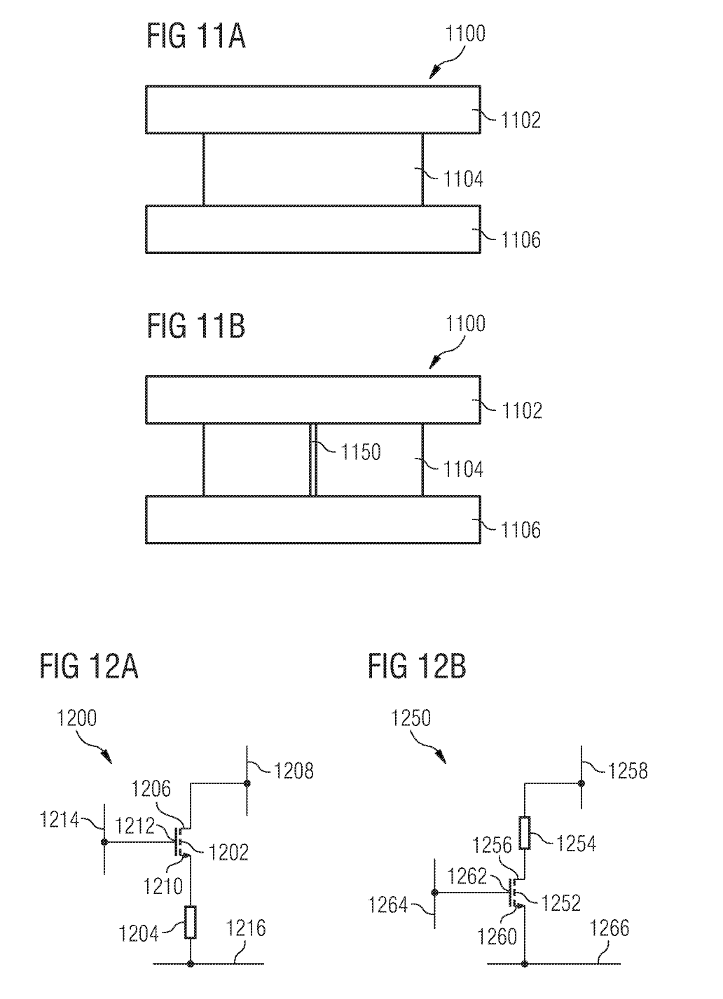

FIG. 11A shows a carbon memory cell 1100 that includes a top contact 1102, a carbon storage layer 1104 including an insulating amorphous carbon material rich in sp³-hybridized carbon atoms, and a bottom contact 1106. As shown in FIG. 11B, by forcing a current (or voltage) through the carbon storage layer 1104, an sp² filament 1150 can be formed in the sp³-rich carbon storage layer 1104, changing the resistivity of the memory cell. Application of a current (or voltage) pulse with higher energy (or, in some embodiments, reversed polarity) may destroy the sp² filament 1150, increasing the resistance of the carbon storage layer 1104. As discussed above, these changes in the resistance of the carbon storage layer 1104 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 12A shows a schematic representation of such a memory cell that uses a resistivity changing memory element. The memory cell 1200 includes a select transistor 1202 and a resistivity changing memory element 1204. The select transistor 1202 includes a source 1206 that is connected to a bit line 1208, a drain 1210 that is connected to the memory element 1204, and a gate 1212 that is connected to a word line 1214. The resistivity changing memory element 1204 also is connected to a common line 1216, which may be connected to ground, or to other circuitry, such as circuitry (not shown) for determining the resistance of the memory cell 1200, for use in reading. Alternatively, in some configurations, circuitry (not shown) for determining the state of the memory cell 1200 during reading may be connected to the bit line 1208. It should be noted that as used herein the terms connected and coupled are intended to include both direct and indirect connection and coupling, respectively.

To write to the memory cell 1200, the word line 1214 is used to select the memory cell 1200, and a current (or voltage) pulse on the bit line 1208 is applied to the resistivity changing memory element 1204, changing the resistance of the resistivity changing memory element 1204. Similarly, when reading the memory cell 1200, the word line 1214 is used to select the cell 1200, and the bit line 1208 is used to apply a reading voltage (or current) across the resistivity changing memory element 1204 to measure the resistance of the resistivity changing memory element 1204.

The memory cell 1200 may be referred to as a 1T1J cell, because it uses one transistor, and one memory junction (the resistivity changing memory element 1204). Typically, a memory device will include an array of many such cells. It will be understood that other configurations for a 1T1J memory cell, or configurations other than a 1T1J configuration may be used with a resistivity changing memory element. For example, in FIG. 12B, an alternative arrangement for a 1T1J memory cell 1250 is shown, in which a select transistor 1252 and a resistivity changing memory element 1254 have been repositioned with respect to the configuration shown in FIG. 12A. In this alternative configuration, the resistivity changing memory element 1254 is connected to a bit line 1258, and to a source 1256 of the select transistor 1252. A drain 1260 of the select transistor 1252 is connected to a common line 1266, which may be connected to ground, or to other circuitry (not shown), as discussed above. A gate 1262 of the select transistor 1252 is controlled by a word line 1264.

According to one embodiment of the present invention, memory devices of improved quality and reproducibility are provided.

In the following description, further aspects of the present invention will be explained.

The invention describes VC patterning first for the CBRAM technology

According to one embodiment of the present invention, a delamination of the chalcogenide during the VC via formation is avoided.

In standard fabricating methods, the top BEOL contact to the CBRAM chalcogenide plate is done after the PL patterning process (patterning process of the composite structure including a solid electrolyte layer and an electrode layer arranged above the solid electrolyte layer). When using the standard tungsten deposition after the VC etch, a delamination of the patterned chalcogenide is created.

According to one embodiment of the present invention, the VC tungsten plug can be generated before the chalcogenide patterning, and the tungsten deposition can be done by a PVD process at lower temperature (less than 300° C.). Without patterned chalcogenide and low W temperature deposition, the delamination can be avoided.

According to one embodiment of the present invention, the VC contact will be done before the PL patterning using a PVD tungsten deposition. The VC patterning will be achieved by the etch of the tungsten and a subsequent oxide deposition. The oxide deposited is used as a hard mask during the PL etching process. After the PL etching process a new oxide deposition will be done and planarized by a CMP process in order to open the VC plug.

According to one embodiment, the PL etch is carried out first, followed by the VC etch and a filling process of tungsten at a deposition temperature of 350° C.

According to one embodiment of the present invention, the integration scheme is as follows:

Chalcogenide+silver deposition

TaN deposition (anneal can be done if necessary)

PVD Tungsten deposition

litho-etch patterning (VC level),

Oxide deposition (hard mask)

litho-etch patterning (PL level),

Oxide deposition (VC ILD)

Oxide CMP planarization (stop on w)

As used herein, the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A method of manufacturing an integrated circuit comprising a resistivity changing memory device, the method comprising:
providing a composite structure comprising a resistivity changing layer and a first conductive layer disposed on or above the resistivity changing layer;
forming a second conductive layer on or above the first conductive layer; and
patterning the second conductive layer such that at least a part of the patterned second conductive layer is usable as a via for contacting the first conductive layer.

2. The method according to claim 1, further comprising providing an isolation layer over the patterned second conductive layer, a thickness of the isolation layer being reduced until a vertical level of a top surface of the isolation layer equals or falls below a vertical level of a top surface of the patterned second conductive layer.

3. The method according to claim 1, further comprising patterning the composite structure after having patterned the second conductive layer.

4. The method according to claim 1, wherein the second conductive layer comprises or consists of tungsten.

5. The method according to claim 1, wherein forming the second conductive layer comprises depositing the second conductive layer using a PVD process.

6. The method according to claim 5, wherein the PVD process is carried out at temperatures below 300° C.

7. The method according to claim 1, wherein the resistivity changing layer comprises or consists of chalcogenide.

8. The method according to claim 2, wherein the thickness of the isolation layer is reduced using a chemical mechanical polishing process.

9. The method according to claim 5, wherein the material of the second masking layer comprises or consists of insulating material.

10. The method according to claim 1, wherein the patterning of the second conductive layer comprises:
depositing a first masking layer over the second conductive layer;
patterning the first masking layer using a lithography process; and
patterning the second conductive layer, wherein the patterned first masking layer serves as a mask for patterning the second conductive layer.

11. The method according to claim 3,
wherein patterning the composite structure comprises:
depositing a second masking layer over the composite structure;
patterning the second masking layer using a lithography process; and
patterning the composite structure, wherein the patterned second masking layer serves as a mask for patterning the composite structure.

12. The method according to claim 2, further comprising patterning the composite structure by depositing a second masking layer over the composite structure, patterning the second masking layer using a lithography process, and patterning the composite structure, wherein the patterned second masking layer serves as a mask for patterning the composite structure, and
wherein the isolation layer is provided on the patterned second masking layer.

13. The method according to claim 12, wherein the material of the second masking layer comprises or consists of the same material as that of the isolation layer.

14. A method of manufacturing an integrated circuit comprising a resistivity changing memory cell, the method comprising:
providing a composite structure comprising a resistivity changing layer and a first conductive layer arranged on or above the resistivity changing layer;
forming a second conductive layer on or above the first conductive layer;
forming a first masking layer on or above the second conductive layer;
patterning the first masking layer;
patterning the second conductive layer such that at least a part of the patterned second conductive layer is usable as a via for contacting the first conductive layer, wherein the patterned first masking layer serves as a mask for patterning the second conductive layer;
removing the patterned first masking layer;
depositing a second masking layer on or above the composite structure;
patterning the second masking layer;
patterning the composite structure, wherein the patterned second masking layer serves as a mask for patterning the composite structure;
depositing an isolation layer on or above the patterned composite structure; and
reducing a thickness of the isolation layer until a vertical level of a top surface of the second isolation layer equals or is lower than a vertical level of a top surface of the structured second conductive layer.

15. The method according to claim 14, wherein reducing the thickness reduction comprises using a chemical mechanical polishing process.

16. The method according to claim 14, wherein the second conductive layer comprises or consists of tungsten.

17. The method according to claim 14, wherein forming the second conductive layer comprises depositing using a PVD process.

18. The method according to claim 17, wherein the PVD process is carried out at temperatures below 300° C.

19. An integrated circuit comprising a memory device, comprising:
a composite structure comprising a resistivity changing layer and an electrode layer disposed above the resistivity changing layer; and
at least one conductive via arranged above the electrode layer, wherein the at least one conductive via directly contacts the electrode layer.

20. The integrated circuit according to claim 19, wherein the at least one via comprises or consists of tungsten.

21. The integrated circuit according to claim 19, wherein the at least one via is embedded into a layer of insulating material, wherein a vertical level of a top surface of the layer of insulating material equals or is lower than a vertical level of a top surface of the at least one via.

22. The integrated circuit according to claim 19, wherein the electrode layer comprises a lower part and an upper part consisting of different materials, respectively.

23. The integrated circuit according to claim 22, wherein the lower part comprises or consists of silver, and the upper part comprises or consists of tantalum nitride or copper.

24. The integrated circuit according to claim 22, wherein the upper part has a thickness of about 100 nm.

25. The integrated circuit according to claim 22, wherein the at least one via has a thickness of about 300 nm.

26. The integrated circuit according to claim 19, wherein the memory device comprises a programmable metallization device.

27. The integrated circuit according to claim 26, wherein the programmable metallization device comprises a solid electrolyte memory device.

28. A cell, comprising:
a composite structure comprising a resistivity changing layer and an electrode layer disposed above the resistivity changing layer; and
at least one conductive via arranged above the electrode layer, wherein the at least one conductive via directly contacts the electrode layer.

29. A resistivity changing memory device, comprising:
a composite structure means including a resistivity changing means and an electrode means arranged on or above the resistivity changing means; and
at least one conductive via means arranged on or above the electrode means, wherein the at least one conductive via means directly contacts the electrode means.

30. A memory module comprising at least one resistivity changing memory device comprising:
a composite structure comprising a resistivity changing layer and an electrode layer disposed above the resistivity changing layer; and
at least one conductive via arranged above the electrode layer, wherein the at least one conductive via directly contacts the electrode layer.

31. The memory module according to claim 31, wherein the memory module is stackable.

32. A computing system comprising:
an input apparatus;
an output apparatus;
a processing apparatus; and
a memory, the memory comprising a composite structure comprising a resistivity changing layer and an electrode layer disposed above the resistivity changing layer, and at least one conductive via arranged above the electrode layer, wherein the at least one conductive via directly contacts the electrode layer.

33. The computing system according to claim 32, wherein at least one of the input apparatus and the output apparatus comprises a wireless communication apparatus.
